(19) United States
(12) Patent Application Publication
(10) Pub. No.: US 2008/0173535 A1
(43) Pub. Date: Jul. 24, 2008

(54) Magnetron Sputtering Source, Sputter-Coating Installation, and Method for Coating a Substrate

(75) Inventor: Joerg Krempel-Hesse, Eckartsborn (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/904,299

(22) Filed: Sep. 24, 2007

(30) Foreign Application Priority Data
Nov. 14, 2006 (EP) 06124060.2

(51) Int. Cl. C23C 14/35; C23C 14/56

(52) U.S. Cl. 204/192.12; 204/298.16; 204/298.12

(57) ABSTRACT

A magnetron sputter source for a sputter-coating installation includes a cathode and a target assigned to the cathode or formed as the cathode. The target provides coating and/or treatment material for the coating and/or treatment of a substrate. Furthermore, the magnetron sputtering source has means for generating a coating plasma and a magnet arrangement for generating a magnetic field for the purpose of influencing the coating plasma such that a plasma channel is generated above a partial section of a surface of the target. The magnet arrangement and the surface of the target are arranged such that they can be moved relative to each other, and the plasma channel is traversable above the surface of the target. The magnetron sputtering source is adjustable such that, when the plasma channel moves over the surface of the target, a duration of exposure of the surface to the plasma is reduced by an increase in a relative velocity (v, v+u) between the magnet arrangement and the target.

### TECHNICAL FIELD

The invention concerns a magnetron sputtering source for a coating installation, comprising at least one cathode and at least one target assigned to the cathode or integrated in the cathode, which provides coating and/or treatment material for coating and/or treatment, means for generating a coating plasma, at least one magnet arrangement for generating a magnetic field for influencing the coating plasma in such a manner that at least one plasma channel is generated above a partial surface of the target, with the magnet arrangement and the target arranged such that they may be moved relative to each other, preferably by means of at least one drive. Additionally, the invention relates to a sputter-coating installation, comprising at least one treatment or coating chamber, and a magnetron sputtering source. The invention also relates to a method for treatment, especially for coating a substrate, comprising the steps:

a) Provision of a treatment or coating installation having a target;

b) Generation of a coating plasma;

c) Generation of a magnetic field for the purpose of influencing the coating plasma such that at least one plasma channel is generated at least above a partial surface of the target; and

d) Generation of a relative movement between the magnetic field and the target.

### PRIOR ART

Different methods are known for the coating of substrates or substrate surfaces, especially for the coating or treatment of large-area substrates. The coating processes employed must also be suitable for producing thin layers of large homogeneity and uniformity. Additionally, for the sake of economical operation of coating installations, it is necessary to reduce the installation size and to achieve a high substrate throughput such that layer systems can be offered at acceptable prices. Under these conditions, great efforts are being undertaken to achieve high-quality layer systems, including large-area substrates, through the use of efficient coating methods.

Sputtering or (cathodic) atomization is a technology frequently used for the production of thin films on substrates. In sputtering methods, a target is bombarded with ions, for example with inert gas ions from an ignited plasma. As a result, the material, which is directly or indirectly intended to serve as the coating, is sputtered from the target, i.e. released or atomised. The sputtered material is deposited, perhaps after a chemical reaction, on the substrate facing the target. The substrate can be arranged either stationary relative to the target during the coating process or be transported continuously past the target.

In order that the efficiency of the sputtering process may be increased, so-called magnetron sputtering sources are used. A magnetron sputtering source has a magnet arrangement, which is arranged on the side of the target facing away from the substrate. The magnet system generates a magnetic field and exerts an influence on the coating plasma, which is generated on the substrate side in a region above the target surface. Depending on the shape of the magnetic lines of force, an inhomogeneous plasma structure forms above the surface of the target, said structure leading to non-uniform erosion of the target material. Typically, magnet arrangements are used that generate closed plasma channels, for example in the shape of an elongated oval (race track). The inhomogeneity of the plasma leads to the formation of erosion trenches in the target. As a result, on one hand, the target material may not be completely consumed and, on the other hand, the inhomogeneous removal and the formation of erosion trenches lead to non-homogeneous, and non-uniform coating of the substrate.

In order to counteract this, mobile magnet arrangements have been proposed that temporally change the plasma distribution surface such that essentially homogeneous removal of the target material may be obtained. For example, reciprocating movement of the magnetic field may be produced in order that the erosion trenches may be smoothed.

In addition to the requirement for high coating homogeneity and fullest possible utilization of the target material, there is the requirement for high efficiency on the part of coating installations. The efficiency of known sputtering installations is essentially limited by the high surface temperature of the target that occurs in the regions beneath the plasma channels. Any attempt to increase the sputtering rate and thus the sputtering power increases the energy input per unit area. This leads to surface effects that interfere undesirably with sputtering. The surface effects may consist, e.g., in melting of the target, in local outgassing of the target and in chemical transformations of compounds in the target material. The consequence of these effects is melted targets and thermally induced arcing (arc discharges). The most obvious way to avoid the temperature effects mentioned is to cool the target. The target may accordingly be mounted to a cooled backing plate, for example.

However, even a cooling device can only reduce the temperature of the uppermost atom layers of the target to a limited extent. For example, in the case of ITO sputtering, the maximum possible power density is limited by the occurrence of arcing at power densities greater than approx. 3 W/cm².

### Technical Object

Proceeding therefrom, it is the object of the present invention to provide a magnetron sputtering source, a sputter-coating installation and a method for the treatment of a substrate by means of which the efficiency of the coating process can be increased by increasing the power density.

### Technical Solution

This object is achieved by magnetron sputtering sources in accordance with claims 1 to 3, a sputter-coating installation in accordance with claim 17 and a method in accordance with claim 18.

Accordingly, the inventive magnetron sputtering source for a coating installation comprises at least one cathode and at least one target assigned to the cathode or formed as cathode, said target providing coating and/or treatment material for the coating and/or treatment, means for generating a coating plasma and at least one magnet arrangement for generating a magnetic field for the purpose of influencing the coating plasma such that at least one plasma channel is generated above at least a partial surface of the target. The magnet arrangement and the surface of the target are arranged so that they can be moved relative to each other such that the plasma channel is movable above the surface of the target. The magnetron sputtering source is adjusted such that, for the purpose of reducing the thermal load on the target surface, the duration for which the surface region is exposed to the plasma is reduced by an increase in the relative velocity of the magnet arrangement and the target.

The duration of exposure is calculated as the quotient of the breadth of the plasma channel (the breadth in this connection is the extension of the plasma channel in the direction of movement) projecting onto the surface region, and the scanning velocity. The smaller the area of the plasma channel and the greater the relative velocity is, the shorter is the duration for which a particular region of the target surface is exposed to the plasma channel. For this reason, a combination of a small plasma channel section and a high scanning velocity (e.g. greater than 0.1 m/s) ensures that the duration for which the surface region is exposed is short. The sputtering rate can be adapted to the exposure duration, and especially increased to the extent that, despite a high sputtering rate, undesirable surface effects (still) do not arise. In addition, the area ratio of the total target surface to the plasma channel must be high enough that the surface cools adequately before this mentioned surface region is scanned again. The duration of exposure to the plasma refers to a single movement of the plasma channel above the surface region of the target. The greater the area ratio of full target surface to the area of the plasma channel or the plasma channels is, the longer are the “recovery periods” for the surface regions of the target between two sequential scans/plasma exposures for a given velocity profile along the path of the plasma channel (and on complete scanning of the surface).

The object is also achieved by a magnetron sputtering source for a coating installation comprising at least one cathode and at least one target assigned to the cathode, said target providing coating and/or treatment material for the coating and/or treatment, means for generating a coating plasma and at least one magnet arrangement for generating a magnetic field for the purpose of influencing the coating plasma such that at least one plasma channel is produced above at least one partial surface of the target. The magnet arrangement and the surface of the target are arranged such that they may be moved relative to each other by means of a drive. The drive is adjusted such that the relative movement exceeds a velocity of at least 0.1 m/s during one coating cycle.

The object is also achieved by a magnetron sputtering source for a coating installation comprising at least one cathode and at least one target assigned to the cathode, said target providing coating and/or treatment material for the coating and/or treatment, means for generating the coating plasma and at least one magnet arrangement for generating a magnetic field for the purpose of influencing the coating plasma such that at least one plasma channel is produced above at least one partial surface of the target. The magnet arrangement and the surface of the target are arranged such that they may be moved relative to each other. The magnetron sputtering source is adjusted such that the power density, at least intermittently, reaches a value of at least 5 W/cm², with the relative velocity of the magnet arrangement to the target as a function of power density (and thus the sputtering rate) being high enough to rule out undesirable temperature-induced surface effects on the target surface.

The present invention is based on the realization that it is possible to exploit the thermal inertia of the surface of the target such that coating may be performed at higher power densities and consequently higher sputtering rates. The power density corresponds to the power introduced per cathode unit area into the system. The power density is a function of the sputtering rate.

Through the use of relative velocities greater than 0.1 m/s, the plasma acts much more briefly on a surface region of the target when the plasma channel is moved relative to the surface region. Through the shorter duration of exposure to the plasma during scanning of the surface region, power densities and/or sputtering rates can be increased, without substantial undesirable surface effects occurring on the target surface, e.g. arcing, melting of the target, local outgassing of the target, chemical reactions of compounds in the target etc. The overall outcome is that the energy input into a surface region (with a certain unit area) during a given (short) period can be increased, without surface effects occurring on the target surface. Optionally, the target may be scanned several times by the plasma channel during a coating cycle, in which case the temperature of the uppermost atomic layers of the target is increased much less than is the case for longer, less powerful exposure to the plasma.

In the present application, exposure of the target surface to the plasma shall be taken to mean a situation in which ions generated in the plasma impinge on a surface region of the target surface, interact with the surface in this region and sputter coating material from this region. It goes without saying that long-term exposure heats up the surface, with the result that the aforementioned undesirable surface effects may occur. For this reason, the invention provides for increasing the velocity during surface scanning such that, even at an elevated power density, the thermal inertia of the target can be exploited via the specific heat capacity.

Insofar as a surface region is scanned several times during a coating cycle, attention is preferably paid to ensuring that the period between the two exposure phases is long enough to permit the surface to cool. The extent of heating during scanning depends on the total energy supplied and on the sequence in which the energy is supplied. It was realized that more meaningful energy input sequences are possible than a practically constant supply of total energy with low sputtering rate. The velocity profile is adjusted to the residence time of the plasma above the target surface.

In the context of the invention, the relative movement between the magnet arrangement and the surface of the target is to be widely interpreted. The target or the cathode may move relative to the magnet arrangement. Alternatively, the magnet arrangement may be capable of moving relative to the target or the cathode. It is also conceivable, however, that both components, magnet arrangement and cathode or target, are arranged such that they can be moved relative to each other and relative to the coating installation.

The magnet system is located on that side of the target to be atomized which faces away from the substrate to be coated. The magnet arrangement especially comprises one or more magnets, especially permanent magnets, and at least one yoke.

The magnet system can generate one or more plasma channels, which are arranged next to each other or inside one another. Possible shapes for such plasma channels are race tracks (an essentially elongated, closed oval path), a bone-shaped, a closed path or a closed path resembling a rhombus. The distribution of layer material and the erosion profile of the target can be optimized by selecting a suitable path shape for the scanning process and allowing for the relative velocity, which is dependent on the spatial coordinates, of the plasma channel during a coating cycle. In addition, homogeneous coating of the substrate can be ensured by suitably setting the parameters, e.g. velocity, sputtering rate, path shape, etc.

Since the invention is suitable for all common sputtering processes, for example of sputtering with noble gas (argon, etc.), sputtering with reactive gas (oxygen, nitrogen, NH₃, etc.), all kinds of target materials can be used. These may be, for example, metals, metal alloys, or metal-nonmetal compounds, such as ITO, IZO, ZnO:Al, SiO₂, IGZO (InGaZnO).

At the two reversal points or reversal sections of the movement of the magnet system, the thickness of the target can be increased relative to the thickness of the material across the remaining target surface, since greater erosion naturally occurs in the reversal regions due to the velocity profile. By means of this measure, a minimum and uniform residual target thickness can be achieved across the entire target at the end of the target service life, with the advantage of commensurately high target utilization. In addition, the perpendicular distance between the magnet system and the back side of the target in the reversal regions can be increased and/or the power input in the reversal regions reduced in order that faster erosion in these regions may be prevented, compared with the other surface regions. In all other respects, better coating results are obtained if the reversal region lies in the boundary region of the target, since higher yields are desired in this region for the purpose of uniform coating.

In the sense of the claims, a surface region of the target is an area on the surface of the target that is small compared with the entire surface exposed to the plasma channel during scanning, especially the partial surface of the target covered by the plasma channel. The surface region can be an infinitesimally small region, by means of which at any rate the influence and/or the effect of the plasma moved over the region is determined.

The advantages of the inventive magnetron sputtering source lie primarily in the possibility of using higher sputtering rates. By combining the higher sputtering rates with an unchanged cycle time, the coating installation can be shortened, a fact which leads to a reduction in procurement and operating costs. Additionally, it has transpired that, with the inventive concept, large-area coatings to be deposited statically (e.g. TFT coatings) can be realized with substantially more homogeneous layer thickness distributions than is the case for conventional technologies that use several parallel cathodes.

In a special embodiment of the invention, the drive is adjusted such that, during a coating cycle, a relative movement velocity of at least 0.1 m/s, especially of 0.2 m/s, especially of 0.3 m/s, especially of 0.5 m/s, especially of 1.0 m/s, especially of 3.0 m/s, especially of 5.0 m/s, is exceeded. The aforementioned high velocities can also be easily realized by means of suitable drives, e.g. belt drives or linear motors.

It transpires that, already at velocities of 0.2 m/s, for example power increases with power densities from hitherto 3 W/cm² to power densities of over 40 W/cm², at velocities of 0.4 m/s power increases to power densities of over 50 W/cm², at velocities of 1.6 m/s for example power increases to power densities of over 55 W/cm², and at velocities of 3.5 m/s to over 70 W/cm² are possible. This surprising effect is especially pronounced even when the velocity is increased from usual levels, e.g. 1.5 mm/s, to over 0.1 m/s.

Each surface region of the target surface is exposed to the coating plasma for a certain length of time during scanning, with the length of time being inversely proportional to the relative rate of movement between the plasma channel and the target surface. This means that the increase in velocity shortens the exposure period of the surface region to the plasma. This in turn makes it possible to use higher sputtering rates during scanning.

The magnet system may reciprocate for the purpose of generating the relative movement for example between the two parallel target edges, especially between the two shorter target edges. This reciprocation can be overlaid with by movements in the remaining directions in space (i.e. not parallel to the central longitudinal axis of the target). The instantaneous velocity, relative to the target surface, can be constant over the largest portion of the path shape. This constant velocity is to at least equal the minimum velocity values specified in the claims. Alternatively, the instantaneous velocity may also be variable in order, e.g., that the layer thickness distributions or target erosion profiles may be adapted. Clearly, where turning points are present and the relative movement slows down, the velocity intermittently drops to lower values or to zero. However, the invention provides that the scanning velocity will exceed the velocity values specified in the claims over a larger portion of the path shape surface during a coating cycle, preferably over 50% of the path length, particularly preferably over 75% of the path length. To an extent depending on the target length, the region scanned at high velocity is in fact even greater.

High reciprocation velocities or large masses on the part of the magnet system can generate vibrations in a coating installation. These vibrations can be counteracted by counterweights.

Especially, the magnetron sputtering source is adjusted such that the power density at least intermittently reaches a value of at least 5 W/cm², especially a value of at least 15 W/cm², especially a value of 30 W/cm², especially a value of 50 W/cm², especially a value of 75 W/cm². The load on the surface of the target that accrues from an increase in the sputtering rate is compensated by an increase in the scanning velocity and thus the duration of exposure of the surface region to the plasma. The inventive magnetron sputtering source is formed or adjusted for operation with such power densities.

In a special embodiment, the setting of the relative velocity between the magnet arrangement and the surface of the target is dependent on the ratio of the size of the total surface area of the target to the area of the plasma channel projected onto the target surface or to that area on the surface of the target which the plasma appreciably acts upon, and on the desired sputtering rate. This is to say nothing other than that the velocity is selected to be high enough to avoid undesirable surface effects at a given high sputtering rate and a given impact area of the plasma channel. From another viewpoint, the velocity is set at a maximum in order that a pertinent maximum sputtering rate, which is empirically determined, may be realized.

Especially, the ratio of the total surface area of the target to the area of the plasma channel is at least 15, especially 30, especially 45, especially 90. The aforementioned area ratio is also important in connection with the other parameters that can be matched with each other, i.e. the velocity profile and the profile of the sputtering rate along the path. This ratio determines the distances at which a specific area of the target surface is under the influence of the plasma. When one or more plasma channels are used, the ratio of the entire sputtering surface area of the target to the area of the plasma channel and/or the plasma channels must be chosen large enough to allow each surface region to cool sufficiently before the next scan. Since the largest possible area ratio guarantees good cooling, the method is particularly suitable for large-area coatings with large-area targets. Additionally, a large area ratio enables an adequately high velocity, combined with high sputtering rates, to be realized. The outcome is that the area ratio indirectly determines the maximum possible sputtering rate via the adjustable velocity.

Such large area ratios are otherwise economically useful only in connection with an increase in power density (and in line with the sputtering rate) and velocity. As a result, despite the large area ratio, short cycle times are obtained during substrate coating.

The sputtering source is preferably adjusted such that the full duration during which a specific surface region of the target is exposed to the plasma per coating cycle is divided into at least two temporally separated time periods.

A coating cycle is considered to be a cycle for coating a substrate with proper coating performed in the station. However, a coating cycle may also be regarded as a temporally closed coating process in which several substrates are coated directly one behind the other.

The significance is that, on account of the high scanning velocity, each surface region of the target is exposed briefly and for two or more times to the plasma during a coating cycle. This approach makes use of the thermal inertia of the target material, which does not heat up excessively during the short scanning period and cools down sufficiently between two scan cycles due to a suitable area ratio (as described above).

The target is preferably formed so as to be rectangular with a length and a breadth, with preferably the length being a multiple of the breadth, and the magnet arrangement and the target being arranged such that they can be moved relative to each other at least along the direction of the length of the target. This movement may be overlaid with movements in other directions in space. Especially, a reciprocating relative movement can be performed between the two transverse edges.

The target may essentially be formed with a flat and/or curved surface. The target may be mounted to a cooled backing plate, for example by bonding, brackets, screws, spraying, etc. The target may be formed either as a planar cathode or as a curved cathode, for example with a size of 2.5 m×0.3 m. Furthermore, the target may be formed as a planar cathode or as curved planar cathode, for example with a size of 2.5 m×2 m. The use of curved cathodes enables in certain cases the layer distribution on the substrate to be controlled or a homogeneous, uniform layer distribution to be obtained on a curved substrate.

The magnetron sputtering source may, however, also be a rotating magnetron tube sputtering source with a tube cathode and/or a rotating tube target. The relative velocity of the target to the magnet system corresponds here to the path velocity of the target surface relative to the magnet system. The area ratio of total surface of the target to the area of the plasma channel may be achieved among other ways by enlarging the target diameter. The inventive principle shall refer, wherever the description specifies flat targets, to every conceivable rotatable cathode/target.

Preferably, at least one anode or anode arrangement is provided for accommodating electrons to be discharged. The anode can be formed by the surroundings of the magnetron cathode, for example the chamber wall, a dark room frame, a peripheral profile, etc.

The anode or anode arrangement may, however, have especially at least one electrode, which is arranged above the target surface so as to be movable relative to the target. In this case, the electrode will usually move synchronously with the magnet system relative to the target. For example, the electrode may be arranged along a plasma channel.

The anode or anode arrangement may have a plurality of electrodes, which are arranged above the target surface relative to the target so as to be immovable or fixed. Thus, the anodes may be made up of one or more cooled or uncooled rods that are located in front of the target or the edge of the target and/or parallel to the magnet system along the movement direction of the magnet system. The electrodes project punctiformly into the plasma channel and are electrically switched in synchronization with the movement of the magnet system.

The target may preferably consist of one or more segments, which are galvanically coupled or isolated. If the target is divided into uncoupled segments, means can be provided for making one segment act as cathode, while at least one adjacent segment is made to act as anode. The electric potential of the individual target segments can be synchronized with the movement of the magnet system, i.e. the target segments can be electrically switched/stepped in synchronization with the movement of the magnet system. The negative sputtering potential is present, for example, only at that target segment which is being passed at that given time by the magnet system. The remaining target segments are not at sputtering potential, but for example at ground, positive or floating potential. Through the use of the anodes or anode arrangements, arcing and undesirable secondary plasmas, such as arc discharges, can be avoided.

The means for generating a coating plasma may have a power-supply device, which comprises an AC (alternating current), DC (direct current), a unipolar pulsed, a bipolar pulsed or an RF (radio frequency) source. The power is coupled into the system from this source.

The inventive object is also achieved with a sputter-coating installation, comprising at least one treatment or coating chamber, and a magnetron sputtering source.

Furthermore, the object is achieved by a method for the treatment of a substrate, especially for the coating of a substrate, comprising the steps:

a) Provision of a treatment or coating installation having a target, especially a treatment or coating installation as mentioned above;

b) Generation on the substrate side of a coating plasma at least above a partial surface of the target surface;

c) Generation of a magnetic field for purpose of influencing the coating plasma such that at least one plasma channel is generated at least above a partial surface of the target; and

d) Generation of a relative movement between the magnetic field and the target.

For the purpose of reducing the thermal load on the target surface, the duration of exposure of the surface region to the plasma is reduced by an increase in the relative velocity between the magnet arrangement and the target.

Additionally, the object is achieved by a method for the treatment of a substrate, especially for the coating of a substrate, comprising the steps:,

a) Provision of a treatment or coating installation having a target, especially a treatment or coating installation as mentioned above;

b) Generation on the substrate side of a coating plasma at least above a partial surface of the target surface;

c) Generation of a magnetic field for purpose of influencing the coating plasma such that at least one plasma channel is generated at least above a partial surface of the target; and

d) Generation of a relative movement between the magnetic field and the target.

The relative velocity between the magnetic field and the target exceeds a value of at least 0.1 m/s.

The plasma channel is guided at high velocity (relative) over a surface region of the target such that a time period in which the plasma continuously acts on the surface region is shortened such that, even at a high power density (and thus high sputtering rate), no substantial undesirable surface effects occur on the target surface.

Especially, the relative velocity of the plasma channel relative to the surface of the target exceeds a value of 0.1 m/s, especially of 0.2 m/s, especially of 0.3 m/s, especially of 0.5 m/s, especially of 1.0 m/s, especially of 3.0 m/s, especially of 5.0 m/s.

Especially, the plasma channel has an oval, elongated oval, bone-shaped or rhombic shape.

During the relative movement between the magnetic field and the surface of the target, the power density reaches at least intermittently a value of at least 5 W/cm², especially a value of at least 15 W/cm², especially a value of 30 W/cm², especially a value of 50 W/cm², especially a value of 75 W/cm². The inventive magnetron sputtering source is formed or adjusted for operation with such power densities.

The magnetic field influences the plasma for the purpose of forming at least one plasma channel, especially in an oval shape (race track), a bone-like shape and/or a rhombus.

In the method mentioned, a ratio of the entire sputtering surface area of the target to the area of the plasma channel projected onto the surface of the target exceeds a value of 15, especially of 30, especially of 45, especially of 90. If the plasma channel generated in step c) has a small area relative to the area of the target, then the time intervals between which a surface region of the target surface is scanned are relatively large.

Especially, the target is formed so as to be rectangular with a length and breadth, with the length being a multiple of the breadth, and the magnetic field moving at least along the direction of the length of the target relative to the target. Especially, the magnetic field can reciprocate relative to the edges of the target.

The total duration of exposure of a certain surface region of the target to the plasma can be divided per coating cycle into at least two temporally separated time periods.

All of the features described are to be claimed in connection with the devices and the method, both individually and in any combination.

### BRIEF DESCRIPTION OF THE DRAWINGS

Further features, and advantages of the invention are apparent from the following description of preferred embodiments using the enclosed drawings. These show in

FIG. 1 A cross-sectional view of an inventive coating installation;

FIG. 2 A lateral view of an inventive coating installation;

FIG. 3 A cross-sectional view of an inventive magnetron sputtering source;

FIG. 4 A plan view of a section of a sputtering source in accordance with the invention during operation;

FIG. 5 A lateral view of a section of a sputtering source in accordance with the invention during operation

FIG. 6 A lateral view of a section of a further sputtering source in accordance with the invention during operation;

FIG. 7 A plan view of an inventive sputtering source;

FIG. 8 A rotatable cathode in the context of the invention; and

FIG. 9 A diagram outlining the dependence between the set velocity, and the power density.

### WAYS TO EXECUTE THE INVENTION

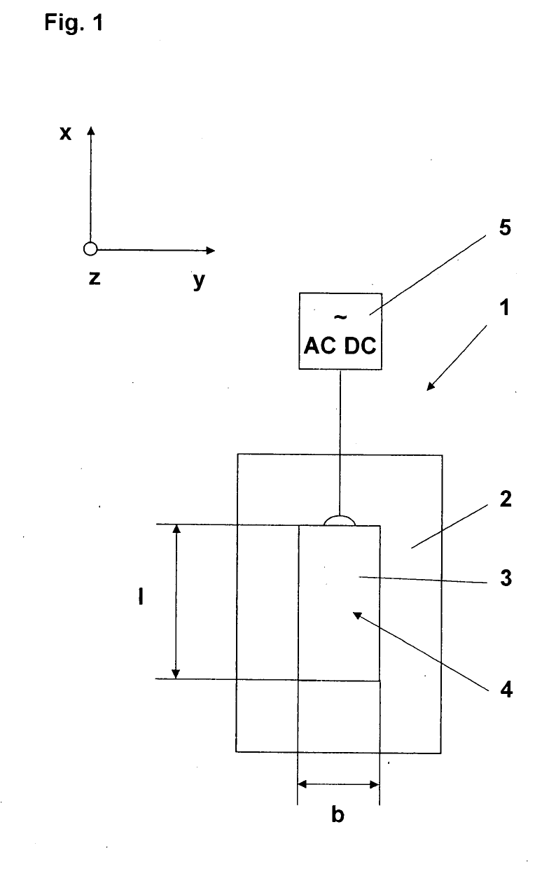

FIG. 1 shows an inventive coating installation 1 in a cross-sectional view. In a coating chamber 2 is arranged an oblong cathode 3 with a length l and breadth b, on which a target 4 is attached. In this view, the cathode 3 lies beneath the target 4 in the plane of the paper. However, cathode 3 and target 4 may also be formed in the context of the invention as an integrated component, i.e. the target material 4 itself may form the cathode 3.

The cathode 3 is connected by a connecting cable to the energy supply 5. The electrical power may be coupled as direct current, alternating current, nonpolar pulsed current, bipolar pulsed current or RF (radio frequency) voltage into the coating system 1.

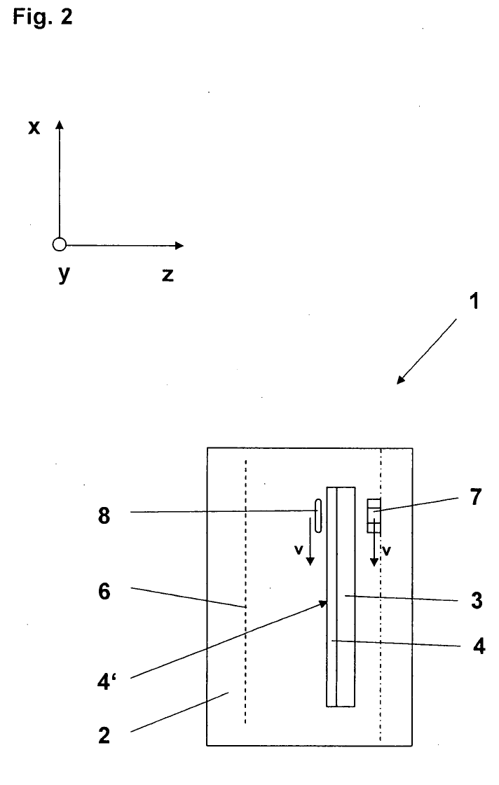

FIG. 2 shows, as indicated by the coordinate system on the top left, a lateral view of the coating installation 1. Inside a coating chamber 2, which is limited by walls are arranged a cathode 3 and the target material 4 attached to the cathode 3. The target material 4 is facing a substrate plane 6 in which the substrates lie during coating or along which the substrates are transported.

Opposite the substrate plane 6, the target 4 with the underlying cathode 3 extends essentially parallel. In this connection, it is pointed out that the target itself may form the cathode. The target 4 must at any rate be at cathode potential.

Behind the cathode arrangement 3, indicated by the arrow v, a magnet system 7 (for example consisting of yoke and magnet, not shown in detail) moves along the longitudinal direction of the cathode 3 or the target 4 at high velocity, for example at 1 m/s. The target 4 is scanned at relatively high velocity v along the length l of the target 4. The magnet system may be driven on a carrier by a drive (not shown).

The magnet system 7 is formed such that it generates a peripheral oval plasma channel 8 (race track) at a distance from the surface. The plasma channel moves across the surface of the target 4 with the same velocity v as the magnet system 7. The direction of movement is indicated by the arrow v. The high scanning velocity prevents local heating of the surface 4′ of the target 4 that could lead to surface effects, such as melting of the target 4, local outgassing or chemical transformations of the compounds in the target 4. Additionally, arcing (heat-induced arc discharge) is prevented.

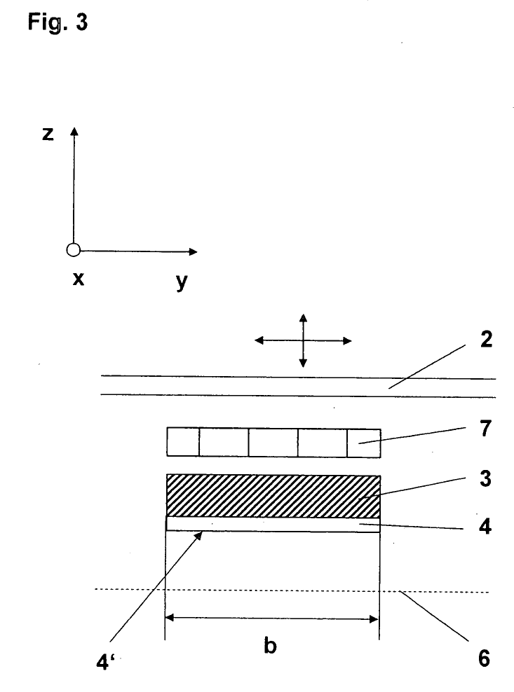

An inventive magnetron sputtering source is shown in FIG. 3.

The surface 4′ of the target 4 points toward the substrate plane 6, and the magnet system 7 is facing away from the substrate plane. The target 4 may be cooled.

The magnet system 7 moves primarily at high velocity in a direction perpendicular to the plane of the paper (x-direction) relative to the target 4. However, overlaid movements in the y- and z-directions are also possible.

A movement of the magnet system 7 relative to the target 4 means that either the magnetic field is reciprocating, for example between the parallel shorter target edges in the x-direction. Or, the target 4 may be driven relative to the magnet system 7, while the magnet system is fixed in position in the coating chamber 2. A movement by the magnet system 7 in the opposite direction to the target 4 would also be conceivable. For example, the target 4 could execute a rapid movement in the x-direction, while the magnet system 7 executes an overlaid movement in the y- and/or z-direction.

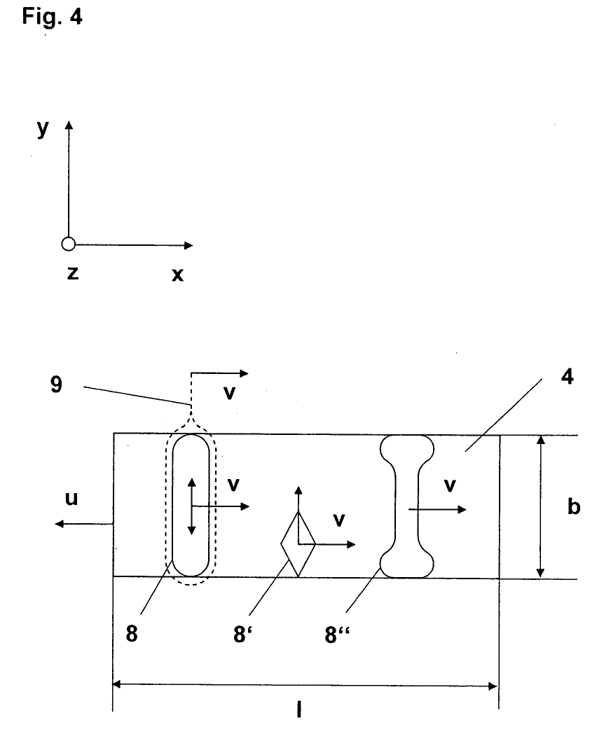

FIG. 4 shows a plan view of a target 4 of an inventive sputtering source.

Beneath the target 4, indicated by the arrows, are arranged magnets or magnet arrangements that may be moved in the x-direction. These move along a scanning path at a velocity, as shown by the arrows v, or with a given velocity profile. An overlaid counter-movement of the target 4 is indicated by the arrow u, such that overall a relative velocity u+v in the x-direction results.

Under suitable conditions, the magnets or magnet systems form plasma channels 8, 8′ 8″ perpendicularly above the surface 4′. These plasma channels 8, 8′, 8″ move together with the magnet systems in the x-direction relative to the target 4 at velocities u+v.

The plasma channels 8, 8′ and 8″ have, for example, different closed configurations, e.g. an elongated oval (race track 8) a rhombic shape 8′, which does not extend across the full breadth b of the target 4, and a bone-shaped area 8″ (each projected onto the target surface 4′). The areas of the plasma channels 8, 8′ and 8″ are small relative to the entire scanned target surface 4′ (both individually and as the sum of the areas 8, 8′, 8″).

For example, an area ratio much greater than 5 is adjusted between the area of the target 4 and the area(s) of the plasma channel(s) 8 or 8′ and 8″. In this way, high relative velocities u+v may be realized in the x-direction between the magnet system 7 and the target 4, for example relative velocities greater than 1 m/s. It has transpired that, through the high relative velocity u+v, combined with the large area ratio, the temperature in the uppermost atomic layers of the target 4 may be markedly reduced relative to conventional arrangements. The better cooling facilitates on the other hand the use of much higher power densities or sputtering rates without interfering surface effects, e.g. melting of the target or arcing.

FIG. 4 additionally shows by way of example an anode 9 arranged near the plasma channel 8, said anode being positioned in the region of the race track. The anode 9 moves synchronously with the magnet system lying under the cathode and thus with the plasma channel 8 at an absolute speed v, thus at a relative velocity u+v, over the surface 4′. The target 4 and/or the magnet system may execute an overlaid relative movement in the y- and/or z-direction, such that a certain erosion profile is selectively adjusted.

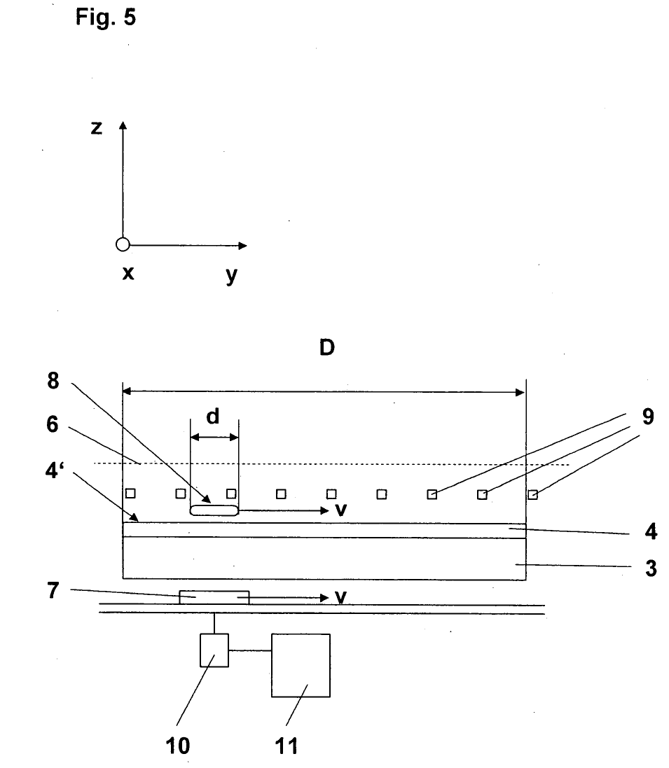

FIG. 5 shows a lateral cross-sectional view of a further embodiment of the invention.

A cathode 3 is provided with target material 4, with the target surface 4′ being aligned with the substrate plane 6.

Beneath the cathode 3 on the side facing away from the substrate plane 6 is the magnet system 7, which may be moved along the x-axis at a velocity v (as indicated in the top left of the Fig.). A plasma channel or race track 8, also at a distance above the surface of the target 4, moves with the magnet system. Of course, in addition to the plasma channel 8, a plurality of further plasma channels may be formed movably in the region above the target surface 4′ by forming the magnet system 7 accordingly.

The plasma channel 8 projects over a region d along a total region D of the target 4 (D corresponds here to the length l of the target). The area ratio of overall target surface to the area of the plasma channel 8 (projected onto the surface of the target 4) is at least 15 in accordance with the invention. This may also apply especially to the ratio D/d. The area of the plasma channel may also be equated roughly with the area of the magnetic yoke, since these parameters are essentially similarly dimensioned.

By means of the magnet system 7, one or more plasma channels (race tracks) 8 may be generated in a region between target 4 and substrate plane 6, said channels capable of being arranged in the form of a pattern alongside each other or inside one another. Especially, the magnet arrangement 7 may be deliberately formed such that a specified layer distribution as well as the erosion profile of the target 4 are optimized.

FIG. 5 also shows an anode arrangement 9 that is immovable relative to the target 4. The anode arrangement 9 may in principle be formed either by the surroundings of the magnetron cathode 3 (for example the chamber wall, a dark room frame, a peripheral profile, etc). In the case shown in FIG. 5, the anode arrangement 9 consists of several adjacent rods, which may be cooled or uncooled. These project punctiformly into the plasma channel 8 and are electrically stepped with the movement of the magnet system 7. Alternatively, one or two electrodes 9 could be provided that move together with the magnet system 7 and are arranged along a plasma channel.

A drive 10 for the magnet system 7 may be provided controlled by a control unit 11 for controlling the scanning velocity and/or the scanning path and/or the power density (and thus the sputtering rate). The control unit 11 may control the sputtering rate, for example as a function of the velocity and/or the spatial coordinates of the magnet system. Due to the high adjusted velocities over the largest portion of the scanning path, power densities far in excess of 3 W/cm², for example power densities of 10 W/cm², 50 W/cm² or even 75 W/cm² may be exceeded.

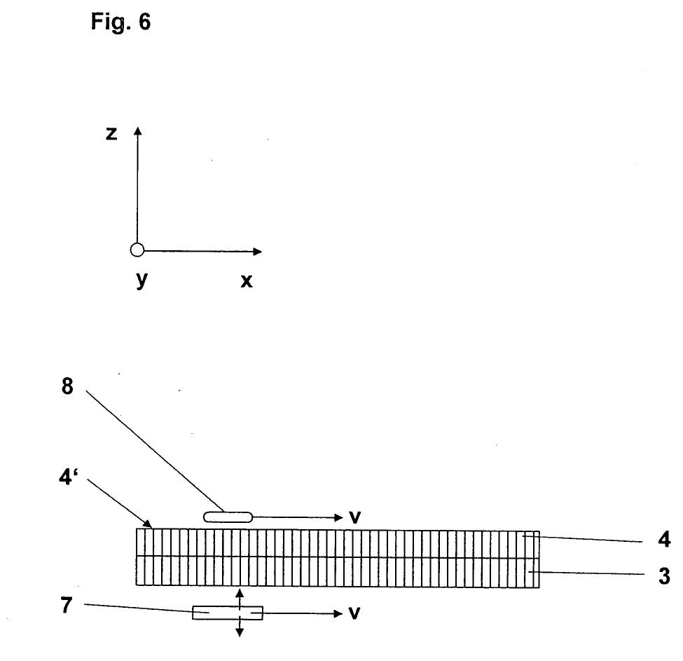

FIG. 6 shows a further embodiment of the invention, with the same elements bearing the same reference symbols used earlier.

In this embodiment, the cathode 3 and the target 4 are segmented. The corresponding target segment(s) in the region of the plasma channel 8 are at cathode potential, while the adjacent corresponding target segments function as anode. In this embodiment, the segments are switched together with the movement of the magnet system 7 and the plasma channel 8, and correspondingly with a velocity v.

The distance between the segments preferably corresponds to the dark room distance in order that electrical flash-overs between adjacent segments that are at different potential may be avoided. In FIG. 6, the indication of size ratios is purely schematic.

The arrows on the magnet system 7 that point in the z-direction are intended to indicate that the magnet system 7 can overlay movements in the x-direction with movements, for example in the z- and also in the y-directions.

Overall, the invention is suitable for a series of conventional sputtering processes, for example sputtering with noble gas (argon, etc.), but also for sputtering processes with reactive gases (oxygen, nitrogen, NH₃, etc).

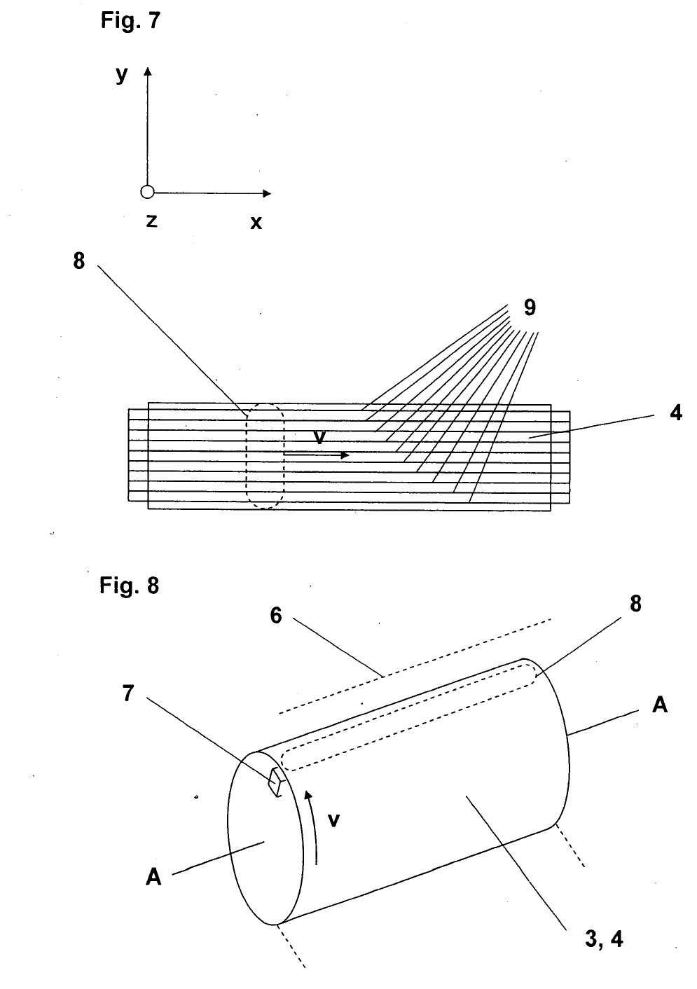

FIG. 7 discloses a further inventive sputtering source, which differs from the hitherto presented embodiments in having an anode arrangement, which is arranged parallel to the direction of movement v of the magnet system 7 or the plasma channel 8.

FIG. 8 shows a rotatable cathode in the context of the invention. The increased relative velocity is marked on the surface of the target as the path velocity v. The scanned target length here corresponds to the circumference. Cathode/target 3, 4 rotate about a central axis A. The race track 8 above the magnet system 7 is indicated by dashed lines.

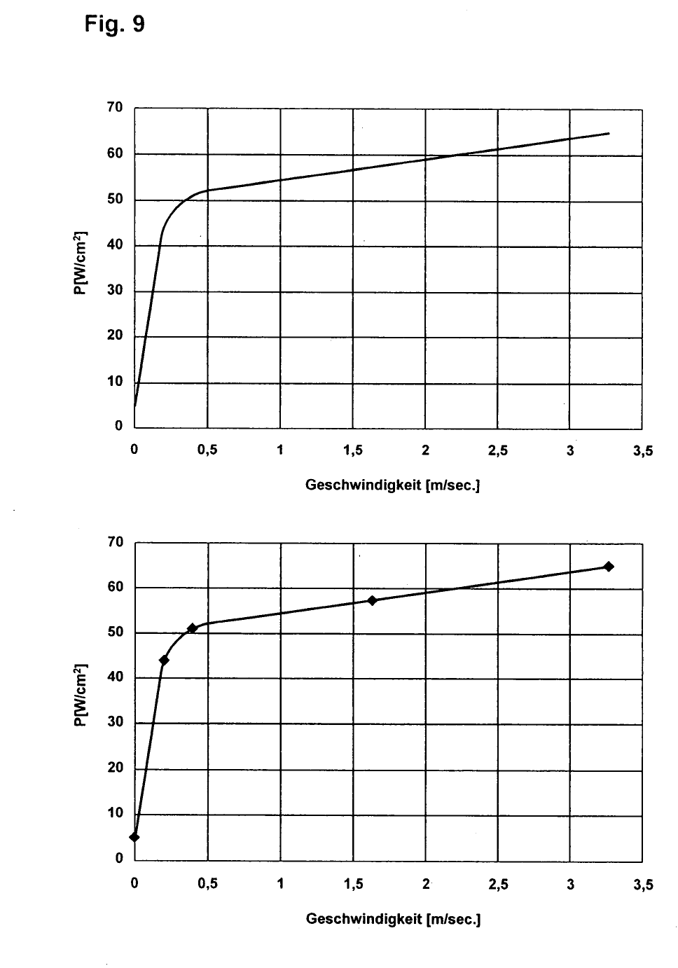

FIG. 9 shows a diagram (in two embodiments with and without measuring points) that illustrates the dependence between the adjusted velocity and the maximum possible power density, i.e. that power density which may be supplied before the target surface starts melting, before arcing occurs or before chemical changes occur in the target surface. A strong rise in the possible supplied power density is already identifiable at velocities of 0.1 m/s. The curve continues to rise at higher relative velocities, but with a smaller gradient (beginning at between approx. 0.3 m/s and 0.4 m/s). Nevertheless, in the higher velocity regions, too, an increase in the velocity still leads to substantial increases in the power density.

The unexpectedly high power densities have not been reached in hitherto conventional velocities in the mm/s region and nor could that have been expected.

1. Magnetron sputtering source for a coating installation, comprising a cathode and a target assigned to the cathode or formed as the cathode, said target providing coating and/or treatment material for the coating and/or treatment,
means for generating a coating plasma,
a magnet arrangement for generating a magnetic field for influencing the coating plasma in such a manner that a plasma channel is generated above a partial section of a surface of the target, with the magnet arrangement and the surface of the target arranged such that the magnet arrangement and the surface of the target may be moved relative to each other,
wherein the magnetron sputtering source is adjustable such that, for the purpose of reducing a thermal load on the surface of the target, the duration for which the surface is exposed to the plasma is reduced by an increase in a relative velocity (v, v+u) between the magnet arrangement and the target.

2. Magnetron sputtering source for a coating installation, comprising a cathode and a target assigned to the cathode or formed as the cathode, said target providing coating and/or treatment material for the coating and/or treatment,
means for generating a coating plasma,
a magnet arrangement for generating a magnetic filed for influencing the coating plasma in such a manner that a plasma channel is generating above a partial section of a surface of the target, with the magnet arrangement and the partial section of a surface of the target arranged such that the magnet arrangement and the surface of the target may be moved relative to each other by a drive,
wherein said drive is adjusted such that a relative movement between the magnet arrangement and the surface of the target exceeds a velocity of at least 0.1 m/s during one coating cycle.

3. Magnetron sputtering source for a coating installation comprising a cathode and a target assigned to the cathode or formed as the cathode, said target providing coating and/or treatment material for the coating and/or treatment,
means for generating a coating plasma,
a magnet arrangement for generating a magnetic field for influencing the coating plasma in such a manner that a plasma channel is generated above a partial section of a surface of the target, with the magnet arrangement and the surface of the target arranged such that the magnet arrangement and the surface of the target may be moved relative to each other,
wherein the magnet sputtering source is adjustable such that the a power density, at least intermittently, reaches a value of at least 5 W/cm², with a relative velocity (v, v+u) of the magnet arrangement and the target being set high enough as a function of the power density and/or a sputtering rate to rule out undesirable temperature-induced surface effects on the surface of the target.

4. The magnetron sputtering source of claim 2, wherein during a coating cycle, the velocity between the magnet arrangement and the surface of the target of exceeds 0.5 m/s.

5. The magnetron sputtering source of claim 3, wherein the magnetron sputtering source is adjusted such that the power density at least intermittently reaches a value of at least 30 W/cm².

6. The magnetron sputtering source of claim 4, wherein the setting of the relative velocity (v, u+v) between the magnet arrangement and the surface of the target is dependent on a ratio of the size of a total surface area of the target to an area of the plasma channel projected onto the surface of the target or to those areas of the plasma channels projected onto the surface of the target and on the desired sputtering rate.

7. The magnetron sputtering source of claim 6, wherein the ratio of the total surface area of the target to the area of the plasma channel or to the areas of the plasma channels is greater than 15.

8. The magnetron sputtering source of claim 1, wherein the magnetron sputtering source is adjustable such that the duration during which a specific surface region of the target is exposed to the plasma per coating cycle is divided into at least two temporally separated time periods.

9. The magnetron sputtering source of claim 1, wherein the target is formed so as to be rectangular with a length (l) and a breadth (b), with the length (l) being a multiple of the breadth (b), and the magnet arrangement and the target being arranged such that the magnet arrangement and the target can be moved relative to each other at least along a direction of the length (l) of the target.

10. The magnetron sputtering source of claim 1, wherein the target comprises a flat and/or curved surface.

11. The magnetron sputtering source of claim 1, wherein the magnetron sputtering source is formed as a rotatable magnetron tube sputtering source with a rotatable tube target.

12. The magnetron sputtering source of claim 1, wherein the magnetron sputtering source has an anode or anode arrangement for accommodating electrons to be discharged.

13. The magnetron sputtering source of claim 12, wherein the anode or anode arrangement has an electrode, which is arranged above the surface of the target so as to be movable relative to the target.

14. The magnetron sputtering source of claim 12, wherein the anode or anode arrangement has a plurality of electrodes, which are arranged above the surface of the target so as to be immovable relative to the target.

15. The magnetron sputtering source of claim 12, wherein the target is divided into uncoupled segments, and means are provided for making at least one segment act as cathode, while at least one adjacent segment is made to act as anode.

16. The magnetron sputtering source of claim 1, wherein the means for generating a coating plasma have a power-supply device, which comprises an AC (alternating current), DC (direct current), a unipolar pulsed, a bipolar pulsed or an RF (radio frequency) source.

17. The magnetron sputtering source of claim 1, wherein sputter-coating installation, comprising a coating and/or treatment chamber, and a magnetron sputtering source.

18. A method for treatment, of a substrate, comprising:
a) providing of a coating installation with a target,
b) generating of a coating plasma on a substrate side above at least a partial section of the surface of the target,
c) generating of a magnetic field for the purpose of influencing the coating plasma such that a plasma channel is produced above a section of the surface of the target, and
d) generating of a relative movement between the magnetic field and the target,
wherein for the purpose of reducing the thermal load on the surface of the target, a duration of exposure of the surface to the plasma is reduced by an increase in a relative velocity between the magnet arrangement and the target.

19. A method for treatment, of a substrate, comprising:
a) providing of a coating installation with a target of claim 17,
b) generating of a coating plasma on the substrate side above at least a section of the surface of the target.
c) generating of a magnetic field for the purpose of influencing the coating plasma such that at least one plasma channel is generated above at least a section of the surface of the target,
d) generating of a relative movement between the magnetic field and the target.
wherein a relative velocity (v, u+v) between the magnetic field and the target exceeds a value of at least 0.1 m/s.

20. The method for treatment of claim 19, wherein during a coating cycle, a relative movement velocity between the magnetic field and the surface of the target of exceeds 0.5 m/s.

21. The method for treatment of claim 18, wherein during the relative movement between the magnetic field and the surface of the target, the power density at least intermittently exceeds a value of at least 5 W/cm².

22. The method for treatment of claim 18, wherein the magnetic field influences the plasma for the purpose of forming a plasma channel, in an oval shape (race track), a bone-like shape and/or a rhombus.

23. The method for treatment of claim 18, wherein a ratio of a total surface area of the target to an area of the plasma channel or to an area of the plasma channels is greater than 15.

24. The method for treatment of claim 18, wherein the target is formed so as to be rectangular with a length (l) and a breadth (b), with the length (l) being a multiple of the breadth (b), and the magnetic field being arranged such that it moves along a direction of the length (l) of the target (4) relative to the target.

25. The method for treatment of claim 18, wherein the total duration of exposure of a specific surface region of the target to the plasma is divided per coating cycle into at least two separated time periods.
